(19) United States
(12) Patent Application Publication
(10) Pub. No.: US 2008/0122457 A1
(43) Pub. Date: May 29, 2008

(54) CAPACITANCE DIFFERENCE DETECTING CIRCUIT

(75) Inventor: Toyoki Taguchi, Yokohama-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/943,130

(22) Filed: Nov. 20, 2007

(30) Foreign Application Priority Data
Nov. 28, 2006 (JP) 2006-320159
Oct. 17, 2007 (JP) 2007-269968

(51) Int. Cl. G01R 27/26

(52) U.S. Cl. 324/679

(57) ABSTRACT

A capacitance difference detecting circuit has timing generator that outputs a current switching pulse signal for controlling a switching operation of a current switching circuit, outputs a gate pulse signal for controlling a chopper amplifier so that the chopper amplifier detects the first charging voltage when a first variable capacitor is charged by a first charging voltage and detects a second charging voltage when a second variable capacitor is charged by a second charging voltage, outputs a first sample pulse signal for controlling a first sampling and holding circuit so that the first sampling and holding circuit samples and holds the output signal of the chopper amplifier when the first charging voltage is detected, and outputs a second sample pulse signal for controlling the second sampling and holding circuit so that the second sampling and holding circuit samples and holds the output signal of the chopper amplifier when the second charging voltage is detected.

### CROSS-REFERENCE TO RELATED APPLICATIONS

This application is based upon and claims the benefit of priority from the prior Japanese Patent Application No. 2006-320159, filed on Nov. 28, 2006, and No. 2007-269968, filed on Oct. 17, 2007, the entire contents of which are incorporated herein by reference.

### BACKGROUND OF THE INVENTION

1. Field of the Invention

The present invention relates to a capacitance difference detecting circuit that detects a small change in capacitance of a micro electro mechanical systems (MEMS) sensor.

2. Background Art

A conventional capacitance difference detecting circuit that detects a small change in capacitance of a MEMS sensor has two LC resonance circuits using a sensor capacitance, a mixer circuit using the difference frequency therebetween, and an F/V converting circuit (a PLL circuit, for example) that converts the frequency of the output of the mixer circuit into voltage (see Japanese Patent Laid-Open No. 2005-326285, for example).

The conventional capacitance difference detecting circuit described above has a problem that the structure is complicated, and the power consumption is high, because the PLL circuit is used.

Another conventional capacitance difference detecting circuit for detecting a small change in capacitance has a main amplifier, a compensating voltage generating circuit and a sampling and holding circuit. Two variable capacitors of a MEMS sensor are discharged, and in this state, a switched capacitor circuit outputs an offset voltage. Then, the compensating voltage generating circuit detects the offset voltage via the main amplifier and generates a compensating voltage that eliminates the offset voltage, and the sampling and holding circuit samples and holds the compensating voltage. Then, the difference in capacitance between the two variable capacitors is converted into voltage, the offset voltage component of the capacitance-difference voltage is cancelled with the compensating voltage from the switched capacitor circuit, and the capacitance-difference voltage reduced in noise and drift is amplified and output (see Japanese Patent Laid-Open Publication No. 9-72757, for example).

For the conventional capacitance difference detecting circuit, the detection gain of the switched capacitor circuit varies with the gain and the feedback capacitance on the side of the detecting circuit, and the variations in the feedback capacitance leads to variations in the detection gain.

Furthermore, for the conventional capacitance difference detecting circuit, the common terminal of the variable capacitors has to be connected to an inverting input terminal (a virtual ground point) that is extremely sensitive to the operation of a switched capacitor amplifier. Typically, the wiring between the sensor and the inverting input terminal is long and therefore is largely affected by a disturbance.

Furthermore, a parasitic capacitance on the wiring may cause the amplifier to oscillate and make the amplifier unusable.

Furthermore, the conventional capacitance difference detecting circuit has many switch components on the sensor input side in order to reduce the offset due to the parasitic capacitance of the feedback path switch of the switched capacitor amplifier.

Therefore, variations in on-resistance of the switches or variations in switching time may cause a large offset.

### SUMMARY OF THE INVENTION

According to one aspect of the present invention, there is provided: a capacitance difference detecting circuit that detects voltages charging a first variable capacitor and a second variable capacitor, the sum of the capacitances of which is constant, and outputs signals corresponding to the voltages to an output terminal, the capacitance difference detecting circuit comprising:

a current source that supplies a charging current to said first and second variable capacitors;

a current switching circuit that is connected between said current source and said first and second variable capacitors and performs a switching operation for supplying the current output from said current source to said first variable capacitor or said second variable capacitor in a complementary manner;

a chopper amplifier that detects a first charging voltage charging said first variable capacitor and a second charging voltage charging said second variable capacitor;

a first sampling and holding circuit that is connected to the output of said chopper amplifier and samples and holds an output signal of said chopper amplifier corresponding to said first charging voltage;

a second sampling and holding circuit that is connected to the output of said chopper amplifier and samples and holds an output signal of said chopper amplifier corresponding to said second charging voltage;

a differential amplifier circuit that receives the output of said first sampling and holding circuit at the inverting input terminal thereof and the output of said second sampling and holding circuit at the non-inverting input terminal thereof and outputs a signal to said output terminal; and

a timing generator that outputs a signal based on a clock signal input thereto,

wherein said timing generator

outputs a current switching pulse signal for controlling the switching operation of said current switching circuit,

outputs a gate pulse signal for controlling said chopper amplifier so that the chopper amplifier detects said first charging voltage when said first variable capacitor is charged by the first charging voltage and detects said second charging voltage when said second variable capacitor is charged by the second charging voltage,

outputs a first sample pulse signal for controlling said first sampling and holding circuit so that the first sampling and holding circuit samples and holds the output signal of said chopper amplifier when said first charging voltage is detected, and

outputs a second sample pulse signal for controlling said second sampling and holding circuit so that the second sampling and holding circuit samples and holds the output signal of said chopper amplifier when said second charging voltage is detected.

According to the other aspect of the present invention, there is provided: a capacitance difference detecting circuit that detects voltages charging a first variable capacitor and a second variable capacitor, the sum of the capacitances of which is constant, and outputs differential signals corresponding to the voltages to a first output terminal and a second output terminal, respectively, the capacitance difference detecting circuit comprising:

a current source that supplies a current to said first and second variable capacitors;

a current switching circuit that is connected between said current source and said first and second variable capacitors and performs a switching operation for supplying the current output from said current source to said first variable capacitor or said second variable capacitor in a complementary manner;

a chopper amplifier that detects a first charging voltage charging said first variable capacitor and a second charging voltage charging said second variable capacitor;

a first sampling and holding circuit that has a first sampling/holding switching circuit connected to the output of said chopper amplifier at one end thereof and a first capacitor connected between the other end of said first sampling/holding switching circuit and the ground and samples and holds the output of said chopper amplifier corresponding to said first charging voltage by charging the first capacitor by the voltage corresponding to the output of said chopper amplifier;

a second sampling and holding circuit that has a second sampling/holding switching circuit connected to the output of said chopper amplifier at one end thereof and a second capacitor connected between the other end of said second sampling/holding switching circuit and the ground and samples and holds the output of said chopper amplifier corresponding to said second charging voltage by charging the second capacitor by the voltage corresponding to the output of said chopper amplifier;

a first differential amplifier circuit that receives the voltage of said first capacitor at the non-inverting input terminal thereof and outputs a signal to said first output terminal;

a second differential amplifier circuit that receives the voltage of said second capacitor at the non-inverting input terminal thereof and outputs a signal to said second output terminal;

a first resistor connected between the output and the inverting input terminal of said first differential amplifier circuit;

a second resistor connected to the inverting input terminal of said first differential amplifier circuit at one end thereof;

a third resistor that is connected between the output and the inverting input terminal of said second differential amplifier circuit and has a resistance equal to the resistance of said first resistor;

a fourth resistor that is connected between the inverting input terminal of said second differential amplifier circuit and the other end of said second resistor and has a resistance equal to the resistance of said second resistor;

a timing generator that outputs a signal based on a clock signal input thereto; and

a control amplifier that amplifies the voltage between said second resistor and said fourth resistor by integration to control said current source,

wherein said timing generator
outputs a current switching pulse signal for controlling the switching operation of said current switching circuit,
outputs a gate pulse signal for controlling said chopper amplifier so that the chopper amplifier detects said first charging voltage when said first variable capacitor is charged by the first charging voltage and detects said second charging voltage when said second variable capacitor is charged by the second charging voltage,
outputs a first sample pulse signal for controlling the first sampling/holding switching circuit of said first sampling and holding circuit so that the first sampling and holding circuit samples and holds the output signal of said chopper amplifier when said first charging voltage is detected, and
outputs a second sample pulse signal for controlling the second sampling/holding switching circuit of said second sampling and holding circuit so that the second sampling and holding circuit samples and holds the output signal of said chopper amplifier when said second charging voltage is detected, and

said control amplifier controls said charging current from said current source so that the voltage between said second resistor and said fourth resistor is equal to a constant reference value.

According to further aspect of the present invention, there is provided: a capacitance difference detecting circuit that detects voltages charging a first variable capacitor and a second variable capacitor, the sum of the capacitances of which is constant, and outputs signals corresponding to the voltages to an output terminal, the capacitance difference detecting circuit comprising:

a current source that supplies a charging current to said first and second variable capacitors;

a current switching circuit that is connected between said current source and said first and second variable capacitors and performs a switching operation for supplying the current output from said current source to said first variable capacitor or said second variable capacitor in a complementary manner;

a first sampling and holding circuit that samples and holds a signal corresponding to a first charging voltage charging said first variable capacitor;

a second sampling and holding circuit that samples and holds a signal corresponding to a second charging voltage charging said second variable capacitor;

a differential amplifier circuit that receives the output of said first sampling and holding circuit at the inverting input terminal thereof and the output of said second sampling and holding circuit at the non-inverting input terminal thereof and outputs a signal to said output terminal;

a timing generator that outputs a signal based on a clock signal input thereto;

a summing amplifier that sums the output of said first sampling and holding circuit and the output of said second sampling and holding circuit and amplifies the sum result; and

a control amplifier that controls said charging current by outputting a control voltage, which is the output of said summing amplifier amplified by integration so that the output of said summing amplifier is equal to a constant reference value, to said current source,

wherein said timing generator

outputs a current switching pulse signal for controlling the switching operation of said current switching circuit,

outputs a first sample pulse signal for controlling said first sampling and holding circuit so that the first sampling and holding circuit samples and holds the signal corresponding to said first charging voltage when said first variable capacitor is charged by said first charging voltage, and

outputs a second sample pulse signal for controlling said second sampling and holding circuit so that the second sampling and holding circuit samples and holds the signal corresponding to said second charging voltage when said second variable capacitor is charged by said second charging voltage.

### BRIEF DESCRIPTION OF THE DRAWINGS

FIG. 1 is a diagram showing a configuration of essential parts of a capacitance difference detecting circuit according to an embodiment 1;

FIG. 2 is a diagram showing waveforms of the pulse signals output from the timing generator shown in FIG. 1 and waveforms of the voltages of the first and second variable capacitors;

FIG. 3 is a diagram showing a configuration of essential parts of a capacitance difference detecting circuit according to an embodiment 2;

FIG. 4 is a diagram showing a configuration of essential parts of a capacitance difference detecting circuit according to an embodiment 3;

FIG. 5 is a diagram showing a configuration of essential parts of a capacitance difference detecting circuit according to an embodiment 4;

FIG. 6 is a diagram showing waveforms of the pulse signals output from the timing generator shown in FIG. 5 and waveforms of the voltages of the first and second variable capacitors;

FIG. 7 is a graph showing relationships between voltages in the conventional capacitance difference detecting circuit and the rate of change of the capacitance of variable capacitors of a MEMS sensor; and

FIG. 8 is a graph showing relationships between voltages in the capacitance difference detecting circuit and the rate of change of the capacitance of variable capacitors of a MEMS sensor.

### DETAILED DESCRIPTION

In the following, embodiments of the present invention will be described with reference to the drawings.

### Embodiment 1

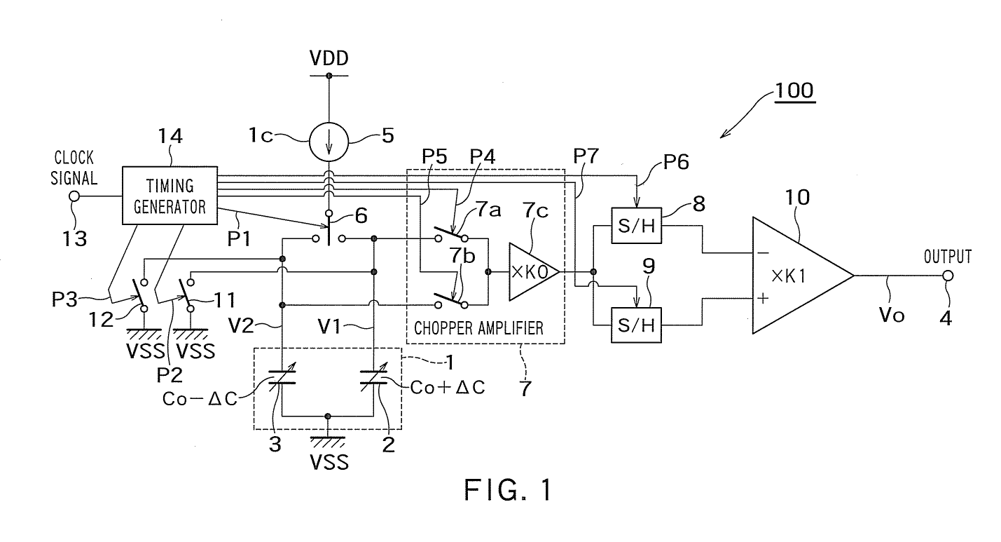

FIG. 1 is a diagram showing a configuration of essential parts of a capacitance difference detecting circuit according to an embodiment 1, which is an aspect of the present invention.

As shown in FIG. 1, a capacitance difference detecting circuit 100 detects the voltages for charging a first variable capacitor 2 and a second variable capacitor 3 forming a MEMS sensor 1, the sum of the capacitances of which is constant. The capacitance difference detecting circuit 100 outputs a signal corresponding to the detected voltages to an output terminal 4.

The capacitance difference detecting circuit 100 has a current source 5 that supplies a charging current to the first and second variable capacitors 2 and 3, and a current switching circuit 6 that is connected between the current source 5 and the first and second variable capacitors 2 and 3.

In this example, the current source 5 is a constant current source.

The current switching circuit 6 performs a switching operation to supply a charging current “Ic” output from the current source 5 to the first variable capacitor 2 and the second variable capacitor 3 in a complementary manner.

The capacitance difference detecting circuit 100 further has a chopper amplifier 7 that detects a first charging voltage “V1” by which the first variable capacitor 2 is charged and a second charging voltage “V2” by which the second variable capacitor 3 is charged, a first sampling and holding circuit 8 connected to the output of the chopper amplifier 7, and a second sampling and holding circuit 9 connected to the output of the chopper amplifier 7.

The chopper amplifier 7 has a first chopper switching circuit 7a connected to the first variable capacitor 2 at one end thereof and a second chopper switching circuit 7b connected to the second variable capacitor 3 at one end thereof.

The chopper amplifier 7 further has an operational amplifier circuit 7c that is connected to the other ends of the first chopper switching circuit 7a and the second chopper switching circuit 7b at the input thereof, amplifies the input signal, and outputs the amplified signal to the first sampling and holding circuit 8 and the second sampling and holding circuit 9.

In this example, the operational amplifier circuit 7c has a gain of K0.

The first sampling and holding circuit 8 samples and holds an output signal of the chopper amplifier 7 corresponding to the first charging voltage “V1”.

Specifically, the first sampling and holding circuit 8 holds a peak voltage “Vp1” (first charging voltage “V1”) expressed by the following formula (1). In this example, reference character “Io” represents the output current of the current source, reference character “To” represents the charge duration of the first and second variable capacitors, reference character “Co” represents the capacitance in the normal state, and reference character “ΔC” represents the small change of the capacitance. In addition, in the formula (1), approximations are made according to ΔP=ΔC/Co and ΔP<<1.

Vp1(V1)=IcTo/(Co+ΔC)≈IcTo(1−ΔP)/Co (1)

The second sampling and holding circuit 9 samples and holds an output signal of the chopper amplifier 7 corresponding to the second charging voltage “V2”.

Specifically, the second sampling and holding circuit 9 holds a peak voltage “Vp2” (second charging voltage “V2”) expressed by the following formula (2). As with the formula (1), in the formula (2), approximations are made according to ΔP=ΔC/Co and ΔP<<1.

Vp2(V2)=IcTo/(Co−ΔC)≈IcTo(1+ΔP)/Co (2)

The capacitance difference detecting circuit 100 further has a differential amplifier circuit 10 that receives the output of the first sampling and holding circuit 8 at the inverting input terminal and the output of the second sampling and holding circuit 9 at the non-inverting input terminal and outputs a signal to the output terminal 4.

The capacitance difference detecting circuit 100 further has a first reset switching circuit 11 connected between the first variable capacitor 2 and the ground and a second reset switching circuit 12 connected between the second variable capacitor 3 and the ground.

In this example, the differential amplifier circuit 10 has a gain of K1. The output of the differential amplifier circuit 10 (that is, the output “Vo” of the capacitance difference detecting circuit 100) is expressed by the following formula (3), which is derived from the formulas (1) and (2).

Vo=K0K1(−V1+V2)≈2IcToΔPK0K1/Co (3)

When the first reset switching circuit 11 is turned on, the first reset switching circuit 11 establishes the connection between the first variable capacitor 2 and the ground to discharge the first variable capacitor 2.

When the second reset switching circuit 12 is turned on, the second reset switching circuit 12 establishes the connection between the second variable capacitor 3 and the ground to discharge the second variable capacitor 3.

The capacitance difference detecting circuit 100 further has a timing generator 14 that outputs a signal for controlling each circuit component based on a clock signal input thereto via a clock signal input terminal 13.

The timing generator 14 outputs a current switching pulse signal “P1” for controlling the switching operation of the current switching circuit 6.

Furthermore, the timing generator 14 outputs a gate pulse signal “P4” for controlling the chopper amplifier 7 so that the first charging voltage “V1” is detected when the first variable capacitor 2 is charged by the first charging voltage “V1”. Specifically, the timing generator 14 outputs a first gate pulse signal “P4” for turning on the first chopper switching circuit 7a when the first variable capacitor 2 is charged by the first charging voltage “V1”.

Furthermore, the timing generator 14 outputs a gate pulse signal “P5” for controlling the chopper amplifier 7 so that the second charging voltage “V2” is detected when the second variable capacitor 3 is charged by the second charging voltage “V2”. Specifically, the timing generator 14 outputs a second gate pulse signal “P5” for turning on the second chopper switching circuit 7b when the second variable capacitor 3 is charged by the second charging voltage “V2”.

Furthermore, the timing generator 14 outputs a first sample pulse signal “P6” for controlling the first sampling and holding circuit 8 so that the first sampling and holding circuit 8 samples and holds the output signal of the chopper amplifier 7 when the first charging voltage “V1” is detected.

Furthermore, the timing generator 14 outputs a second sample pulse signal “P7” for controlling the second sampling and holding circuit 9 so that the second sampling and holding circuit 9 samples and holds the output signal of the chopper amplifier 7 when the second charging voltage “V2” is detected.

Now, an operation of the capacitance difference detecting circuit 100 configured as described above will be described.

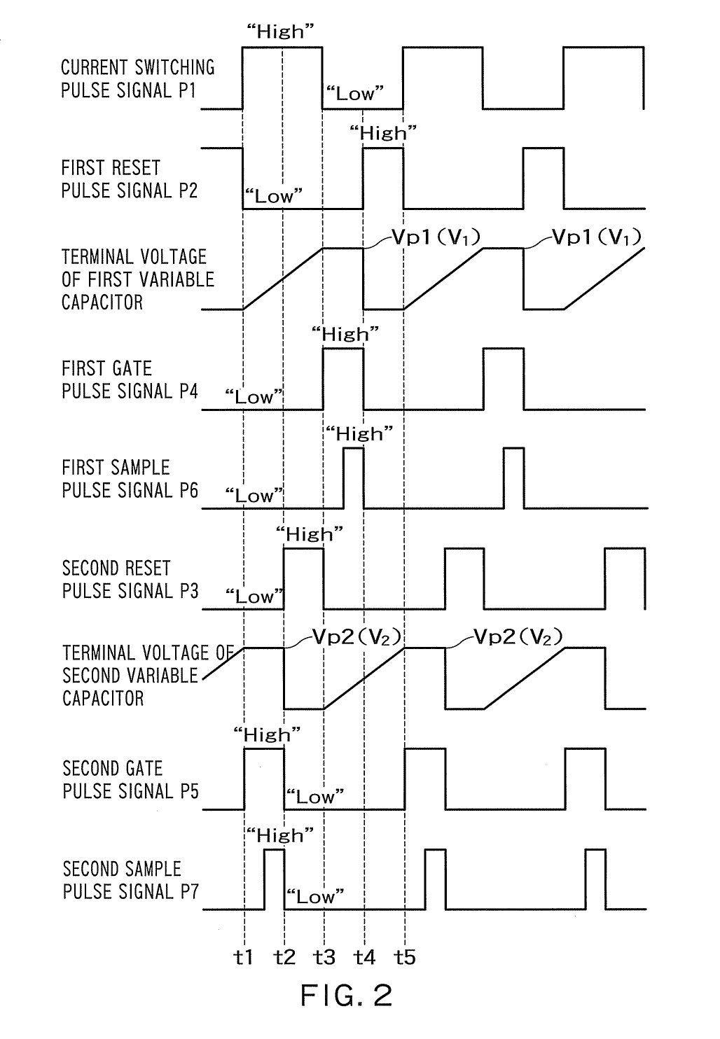

FIG. 2 is a diagram showing waveforms of the pulse signals output from the timing generator shown in FIG. 1 and waveforms of the voltages of the first and second variable capacitors.

As shown in FIG. 2, at a time “t1”, the current switching pulse signal “P1” changes from “Low” to “High” to switch the current switching circuit 6 to flow the charging current “Ic” to the first variable capacitor 2. At the same time, the first reset pulse signal “P2” changes from “High” to “Low” to turn off the first reset switching circuit 11. As a result, charging of the first variable capacitor 2 is started, and the terminal voltage of the first variable capacitor 2 rises.

In addition, at the time “t1”, the second gate pulse signal “P5” changes from “Low” to “High” to turn on the second chopper switching circuit 7b to supply the second charging voltage “V2” to the operational amplifier circuit 7c. Then, the second sample pulse signal “P7” changes from “Low” to “High” to make the second sampling and holding circuit 9 sample and hold the second charging voltage “V2”.

Then, at a time “t2”, the second reset pulse signal “P3” changes from “Low” to “High” to turn on the second reset switching circuit 12. As a result, the second variable capacitor 3 is discharged, and the terminal voltage of the second variable capacitor 3 becomes equal to a ground potential “VSS”.

In addition, at the time “t2”, the second gate pulse signal “P5” changes from “High” to “Low” to turn off the second chopper switching circuit 7b. In addition, the second sample pulse signal “P7” changes from “High” to “Low” to finish sampling and holding of the second charging voltage “V2”.

Then, at a time “t3”, the current switching pulse signal “P1” changes from “High” to “Low” to switch the current switching circuit 6 to flow the charging current “Ic” to the second variable capacitor 3. At the same time, the second reset pulse signal “P3” changes from “High” to “Low” to turn off the second reset switching circuit 12. As a result, charging of the second variable capacitor 3 is started, and the terminal voltage of the second variable capacitor 3 rises.

In addition, at the time “t3”, the first gate pulse signal “P4” changes from “Low” to “High” to turn on the first chopper switching circuit 7a to supply the first charging voltage “V1” to the operational amplifier circuit 7c. Then, the first sample pulse signal “P6” changes from “Low” to “High” to make the first sampling and holding circuit 8 sample and hold the first charging voltage “V1”.

Then, at a time “t4”, the first reset pulse signal “P2” changes from “Low” to “High” to turn on the first reset switching circuit 11. As a result, the first variable capacitor 2 is discharged, and the terminal voltage of the first variable capacitor 2 becomes equal to the ground potential “VSS”.

In addition, at the time “t4”, the first gate pulse signal “P4” changes from “High” to “Low” to turn off the first chopper switching circuit 7a. In addition, the first sample pulse signal “P6” changes from “High” to “Low” to finish sampling and holding of the first charging voltage “V1”.

From a time “t5”, the same operation as that from the time “t1” to the time “t5” is repeated.

The timing generator 14 outputs the current switching pulse “P1” to the current switching circuit 6 so that the duration in which the first variable capacitor 2 is charged by the charging current “Ic” supplied from the current source 5 (from the time “t1” to the time “t3”) and the duration in which the second variable capacitor 3 is charged by the charging current “Ic” supplied from the current source 5 (from the time “t3” to the time “t5”) are equal to each other.

In this way, the variable capacitors arranged in the differential configuration are alternately charged and discharged for a desired period by flowing a small amount of current thereto. The peak values of the sawtooth waves at the terminals of the variable capacitors are alternately sampled and amplified by the same amplifier. Then, the two sampling and holding circuits alternately and independently detect the signals output from the amplifier, and the signals are subjected to a differential calculation. Thus, a small change in capacitance can be converted into voltage.

Since one common operational amplifier circuit is used in the first stage, the offset of the detected outputs can be eliminated.

As described above, the capacitance difference detecting circuit according to this embodiment can quickly and accurately detect a small change in capacitance.

The first gate pulse signal “P4” and the first sample pulse signal “P6” may be the same signal. Similarly, the second gate pulse signal “P5” and the first sample pulse signal “P7” may be the same signal.

### Embodiment 2

In the embodiment 1 described above, the current source that supplies a current to the variable capacitors is a constant current source.

In an embodiment 2, there will be described a configuration in which the current from the current source is adjusted so that the output of the capacitance difference detecting circuit is equal to a constant reference value.

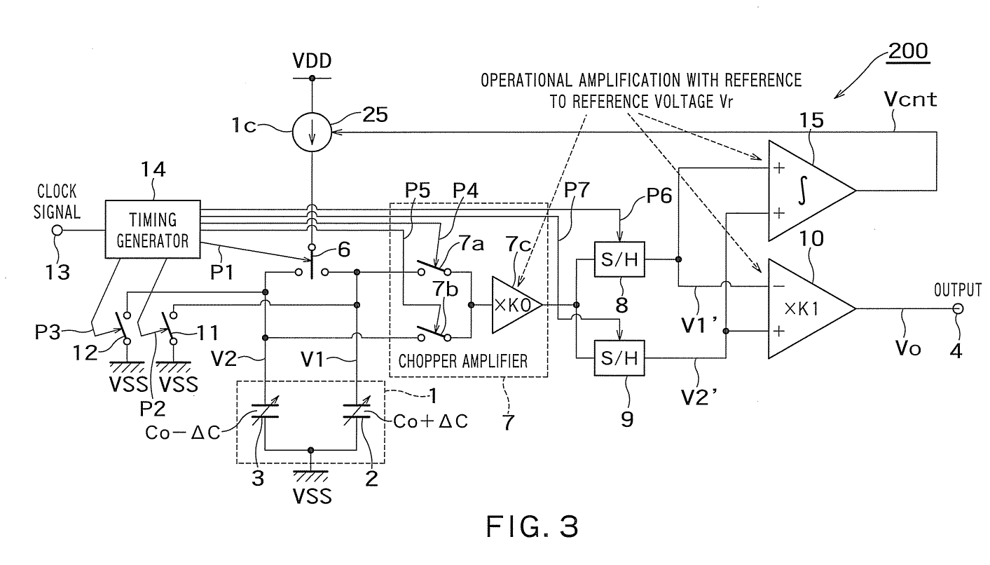

FIG. 3 is a diagram showing a configuration of essential parts of a capacitance difference detecting circuit according to the embodiment 2, which is an aspect of the present invention. In this drawing, the same reference numerals as those in the embodiment 1 shown in FIG. 1 denote the same components as those in the embodiment 1.

As shown in FIG. 3, compared with the embodiment 1, a capacitance difference detecting circuit 200 further has a control amplifier 15 that sums the output of a first sampling and holding circuit 8 and the output of a second sampling and holding circuit 9, amplifies the sum value by integration and outputs a control voltage “Vcnt” to a current source 25. In this example, the current source 25 is a variable current source.

The control amplifier 15 controls a charging current “Ic” from the current source 25 so that the sum of a sampled and held output “V1′” and a sampled and held output “V2′” is equal to a constant reference value (or in other words, so that the sum value is equal to a reference voltage “Vr”, because calculations are performed with reference to the reference voltage “Vr” as described below). In this example, the reference voltage “Vr” is 0.

A first charging voltage “V1” is expressed by the following formula (4).

V1=Vr−ΔPVr (4)

### A second charging voltage “V2” is expressed by the following formula (5).

V2=Vr+ΔPVr (5)

Therefore, the output “Vo” of the capacitance difference detecting circuit 200 is expressed by the following formula (6).

Vo=K0K1(−V1+V2)=2K0K1ΔPVr (6)

In this way, the capacitance difference detecting circuit 200 controls the charging current “Ic” so that the sum of the outputs is equal to a constant value, thereby compensating for variations in output due to the MEMS sensor.

Furthermore, since the sum value is adjusted to be equal to the constant value, the rate of the small change in capacitance is normalized, and variations of the MEMS sensor are automatically compensated for.

The operation of the capacitance difference detecting circuit 200 is the same as that in the embodiment 1 except that the charging current “Ic” is controlled based on the sum value.

As described above, the capacitance difference detecting circuit according to this embodiment can quickly and accurately detect a small change in capacitance while automatically compensating for variations in output.

### Embodiment 3

In the embodiment 2, there has been described a configuration in which the current from the current source is adjusted so that the output of the capacitance difference detecting circuit is equal to a constant reference value.

In an embodiment 3, there will be described another configuration in which the current from the current source is adjusted so that the output of the capacitance difference detecting circuit is equal to a constant reference value.

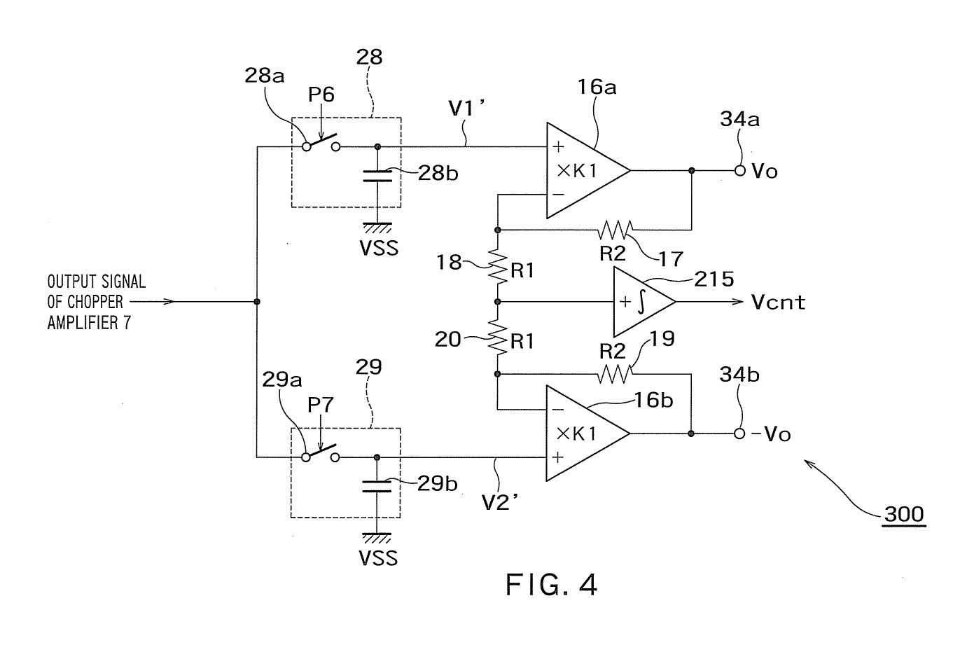

FIG. 4 is a diagram showing a configuration of essential parts of a capacitance difference detecting circuit according to the embodiment 3, which is an aspect of the present invention. In FIG. 4, the components of a capacitance difference detecting circuit 300 other than those corresponding to the first and second sampling and holding circuits, the operational amplifier circuit and the control amplifier in the embodiment 2 shown in FIG. 3, which are different from those in the embodiment 2 shown in FIG. 3, are omitted because the components are the same as those in the embodiment 2.

As shown in FIG. 4, the capacitance difference detecting circuit 300 detects a first charging voltage “V1” and a second charging voltage “V2” by which a first variable capacitor 2 and a second variable capacitor 3, the sum of the capacitances of which is constant, are charged, respectively, and outputs differential signals “Vo” and “−Vo” corresponding to the first charging voltage “V1” and the second charging voltage “V2” to a first output terminal 34a and a second output terminal 34b, respectively.

In addition to the above-described components that are omitted in FIG. 4, the capacitance difference detecting circuit 300 has a first sampling and holding circuit 28, a second sampling and holding circuit 29 and a control amplifier 215.

The first sampling and holding circuit 28 has a first sampling/holding switching circuit 28a connected to the output of a chopper amplifier 7 at one end, and a first capacitor 28b connected between the other end of the first sampling/holding switching circuit 28a and the ground “VSS”.

The first sampling and holding circuit 28 samples and holds the output of the chopper amplifier 7 corresponding to the first charging voltage “V1” by charging the first capacitor 28b by the voltage corresponding to the output of the chopper amplifier 7.

The second sampling and holding circuit 29 has a second sampling/holding switching circuit 29a connected to the output of the chopper amplifier 7 at one end, and a second capacitor 29b connected between the other end of the second sampling/holding switching circuit 29a and the ground “VSS”.

The second sampling and holding circuit 29 samples and holds the output of the chopper amplifier 7 corresponding to the second charging voltage “V2” by charging the second capacitor 29b by the voltage corresponding to the output of the chopper amplifier 7.

The capacitance difference detecting circuit 300 further has a first differential amplifier circuit 16a that receives the voltage of the first capacitor 28b at the non-inverting input terminal and outputs the signal “Vo” to the first output terminal 34a, and a second differential amplifier circuit 16b that receives the voltage of the second capacitor 29b at the non-inverting input terminal and outputs the signal “−Vo” to the second output terminal 34b.

The capacitance difference detecting circuit 300 further has a first resistor 17 connected between the output and the inverting input terminal of the first differential amplifier circuit 16a, a second resistor 18 connected to the inverting input terminal of the first differential amplifier circuit 16a at one end, a third resistor 19 that is connected between the output and the inverting input terminal of the second differential amplifier circuit 16b and has a resistance “R2” equal to that of the first resistor 17, and a fourth resistor 20 that is connected between the inverting input terminal of the second differential amplifier circuit 16b and the other end of the second resistor 18 and has a resistance “R1” equal to that of the second resistor 18.

A timing generator 14 (which is the same as that shown in FIG. 3) outputs a first sample pulse signal “P6” for controlling the first sampling/holding switching circuit 28a so that the first sampling and holding circuit 28 samples and holds the output signal of the chopper amplifier 7 when the first charging voltage “V1” is detected.

The timing generator 14 also outputs a second sample pulse signal “P7” for controlling the second sampling/holding switching circuit 29a so that the second sampling and holding circuit 29 samples and holds the output signal of the chopper amplifier 7 when the second charging voltage “V2” is detected.

The control amplifier 215 controls a current source 25 by amplifying by integration the voltage between the second resistor 18 and the fourth resistor 20. The control amplifier 215 controls a charging current “Ic” from the current source 25 so that the sum of a sampled and held output “V1′” and a sampled and held output “V2′” is equal to a constant reference value (0 in this example), or in other words, the sum value is equal to a reference voltage “Vr”, because calculations are performed with reference to the reference voltage “Vr”.

The output “Vo” of the capacitance difference detecting circuit 300 is expressed by the following formula (7).

Vo=R2/R1(Vp1−Vp2) (7)

In this way, in the capacitance difference detecting circuit 300, the arrangement including the operational amplifier circuit is configured as an instrumentation amplifier, and therefore, the first and second sampling and holding circuits 28 and 29 can be composed only of the first and second sampling/holding switching circuits 28a and 29a and the first and second capacitors, respectively. That is, the structure of the sampling and holding circuits can be simplified.

The operation of the capacitance difference detecting circuit 300 is the same as the operation of the capacitance difference detecting circuit 200 according to the embodiment 2.

As described above, the capacitance difference detecting circuit according to this embodiment can quickly and accurately detect a small change in capacitance while compensating for variations in output.

### Embodiment 4

In the embodiment 2, there has been described a configuration in which the current from the current source is adjusted so that the output of the capacitance difference detecting circuit is equal to a constant reference value.

In an embodiment 4, there will be described a configuration in which the current from the current source is adjusted so that the linearity of variations in output of the capacitance difference detecting circuit with respect to variations in capacitance of the MEMS sensor is improved.

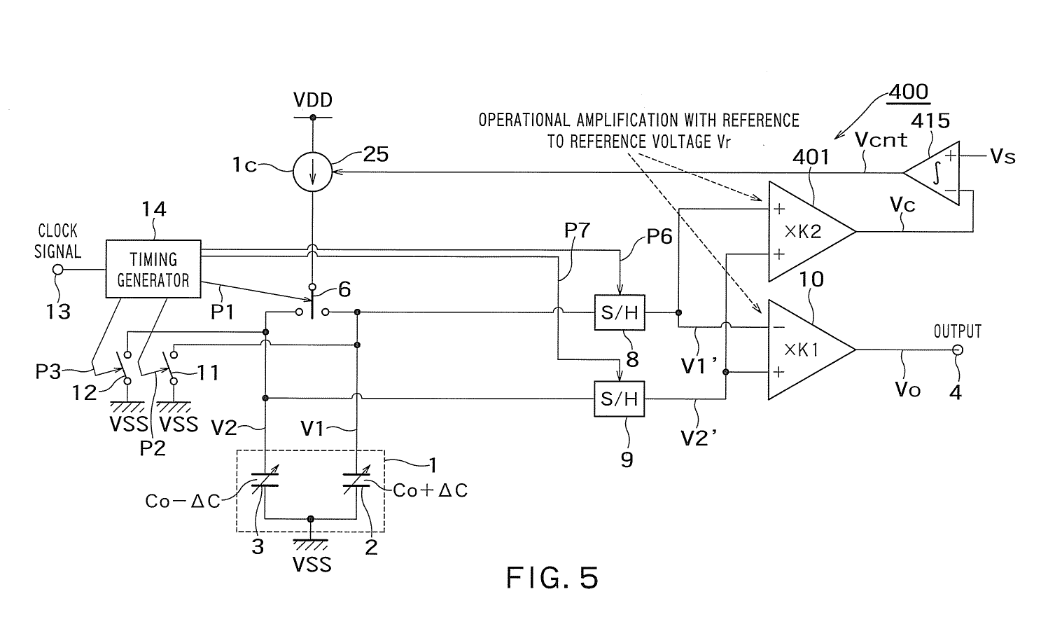

FIG. 5 is a diagram showing a configuration of essential parts of a capacitance difference detecting circuit according to the embodiment 4, which is an aspect of the present invention. In this drawing, the same reference numerals as those in the embodiment 2 denote the same parts as those in the embodiment 2 shown in FIG. 2.

As shown in FIG. 5, a capacitance difference detecting circuit 400 detects the voltages for charging a first variable capacitor 2 and a second variable capacitor 3 forming a MEMS sensor 1, the sum of the capacitances of which is constant. The capacitance difference detecting circuit 400 outputs a signal corresponding to the detected voltages to an output terminal 4.

The capacitance difference detecting circuit 400 has a current source 25 that supplies a charging current “Ic” to the first and second variable capacitors 2 and 3, and a current switching circuit 6 that is connected between the current source 25 and the first and second variable capacitors 2 and 3.

In this example, the current source 25 is a variable current source.

The current switching circuit 6 performs a switching operation to supply a charging current “Ic” output from the current source 25 to the first variable capacitor 2 and the second variable capacitor 3 in a complementary manner.

The capacitance difference detecting circuit 400 further has a first sampling and holding circuit 8 connected to the first variable capacitor 2 at the input thereof. The first sampling and holding circuit 8 samples and holds a first charging voltage “V1” charging the first variable capacitor 2 in response to a first sample pulse signal “P6”.

The capacitance difference detecting circuit 400 further has a second sampling and holding circuit 9 connected to the second variable capacitor 3 at the input thereof. The second sampling and holding circuit 9 samples and holds a second charging voltage “V2” charging the second variable capacitor 3 in response to a second sample pulse signal “P7”.

As described above, the first sampling and holding circuit 8 samples and holds a signal corresponding to the first charging voltage “V1”. In other words, the first sampling and holding circuit 8 holds a peak voltage “Vp1” (the first charging voltage “V1”) expressed by the formula (1) described above.

The second sampling and holding circuit 9 samples and holds a signal corresponding to the second charging voltage “V2”. In other words, the second sampling and holding circuit 9 holds a peak voltage “Vp2” (the second charging voltage “V2”) expressed by the formula (2) described above.

The capacitance difference detecting circuit 400 further has a differential amplifier circuit 10 that receives the output of the first sampling and holding circuit 8 at the inverting input terminal and the output of the second sampling and holding circuit 9 at the non-inverting input terminal and outputs a signal to the output terminal 4.

In this example, the differential amplifier circuit 10 has a gain of K1. The output of the differential amplifier circuit 10 (that is, the output “Vo” of the capacitance difference detecting circuit 400) is expressed by the following formula (8).

Vo=K1(−V1+V2) (8)

The capacitance difference detecting circuit 400 further has a first reset switching circuit 11 connected between the first variable capacitor 2 and the ground and a second reset switching circuit 12 connected between the second variable capacitor 3 and the ground.

When the first reset switching circuit 11 is turned on, the first reset switching circuit 11 establishes the connection between the first variable capacitor 2 and the ground to discharge the first variable capacitor 2.

When the second reset switching circuit 12 is turned on, the second reset switching circuit 12 establishes the connection between the second variable capacitor 3 and the ground to discharge the second variable capacitor 3.

The capacitance difference detecting circuit 400 further has a timing generator 14 that outputs a signal for controlling each circuit component based on a clock signal input thereto via a clock signal input terminal 13.

The timing generator 14 outputs a current switching pulse signal “P1” for controlling the switching operation of the current switching circuit 6.

Furthermore, the timing generator 14 outputs a first sample pulse signal “P6” for controlling the first sampling and holding circuit 8 so that the first sampling and holding circuit 8 samples and holds the signal corresponding to the first charging voltage “V1” when the first variable capacitor 2 is charged by the first charging voltage “V1”.

Furthermore, the timing generator 14 outputs a second sample pulse signal “P7” for controlling the second sampling and holding circuit 9 so that the second sampling and holding circuit 9 samples and holds the signal corresponding to the second charging voltage “V2” when the second variable capacitor 3 is charged by the second charging voltage “V2”.

The capacitance difference detecting circuit 400 further has a summing amplifier 401 that sums the output of the first sampling and holding circuit 8 and the output of the second sampling and holding circuit 9, amplifies the sum value and outputs a voltage “Vc”. The summing amplifier 401 has a gain K2 of 0.5, for example.

The capacitance difference detecting circuit 400 further has a control amplifier 415 that compares the voltage “Vc” output from the summing amplifier 401 and a preset voltage “Vs” and controls the current source 25 so that the voltage “Vc” and the preset voltage “Vs” are equal to each other.

The control amplifier 415 outputs, to the current source 25, a control voltage “Vcnt”, which is the output of the summing amplifier 401 amplified by integration so that the sum of an sampled and held output “V1′” (the first charging voltage “V1”) and a sampled and held output “V2′” (the second charging voltage “V2”) is equal to a constant reference value. Thereby, the control amplifier 415 controls the charging current “Ic”. In this example, for example, the control amplifier 415 controls the charging current “Ic” from the current source so that a half of the sum value is equal to the preset voltage “Vs”.

Now, an operation of the capacitance difference detecting circuit 400 configured as described above will be described.

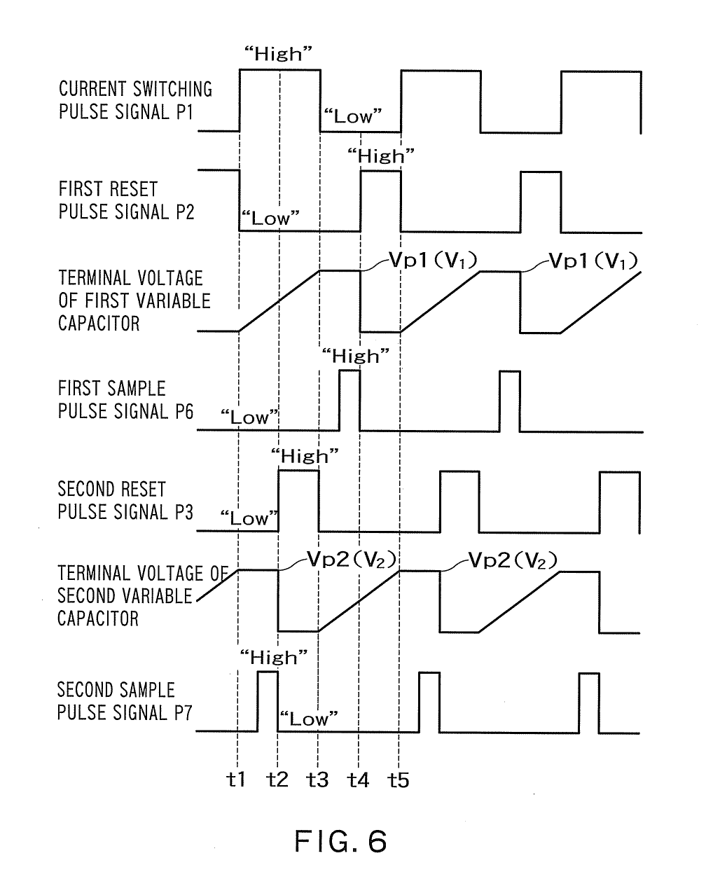

FIG. 6 is a diagram showing waveforms of the pulse signals output from the timing generator shown in FIG. 5 and waveforms of the voltages of the first and second variable capacitors.

As shown in FIG. 6, at a time “t1”, the current switching pulse signal “P1” changes from “Low” to “High” to switch the current switching circuit 6 to flow the charging current “Ic” to the first variable capacitor 2. At the same time, the first reset pulse signal “P2” changes from “High” to “Low” to turn off the first reset switching circuit 11. As a result, charging of the first variable capacitor 2 is started, and the terminal voltage of the first variable capacitor 2 rises.

In addition, from the time “t1” to the time “t2”, the second sample pulse signal “P7” changes from “Low” to “High” to make the second sampling and holding circuit 9 sample and hold the second charging voltage “V2”.

Then, at a time “t2”, the second reset pulse signal “P3” changes from “Low” to “High” to turn on the second reset switching circuit 12. As a result, the second variable capacitor 3 is discharged, and the terminal voltage of the second variable capacitor 3 becomes equal to a ground potential “VSS”.

In addition, at the time “t2”, the second sample pulse signal “P7” changes from “High” to “Low” to finish sampling and holding of the second charging voltage “V2”.

Then, at a time “t3”, the current switching pulse signal “P1” changes from “High” to “Low” to switch the current switching circuit 6 to flow the charging current “Ic” to the second variable capacitor 3. At the same time, the second reset pulse signal “P3” changes from “High” to “Low” to turn off the second reset switching circuit 12. As a result, charging of the second variable capacitor 3 is started, and the terminal voltage of the second variable capacitor 3 rises.

In addition, from the time “t3” to the time “t4”, the first sample pulse signal “P6” changes from “Low” to “High” to make the first sampling and holding circuit 8 sample and hold the first charging voltage “V1”.

Then, at a time “t4”, the first reset pulse signal “P2” changes from “Low” to “High” to turn on the first reset switching circuit 11. As a result, the first variable capacitor 2 is discharged, and the terminal voltage of the first variable capacitor 2 becomes equal to the ground potential “VSS”.

In addition, at the time “t4”, the first sample pulse signal “P6” changes from “High” to “Low” to finish sampling and holding of the first charging voltage “V1”.

From a time “t5”, the same operation as that from the time “t1” to the time “t5” is repeated.

The timing generator 14 outputs the current switching pulse signal “P1” to the current switching circuit 6 so that the duration in which the first variable capacitor 2 is charged by the charging current “Ic” supplied from the current source 5 (from the time “t1” to the time “t3”) and the duration in which the second variable capacitor 3 is charged by the charging current “Ic” supplied from the current source 25 (from the time “t3” to the time “t5”) are equal to each other.

In this way, the variable capacitors arranged in the differential configuration are alternately charged and discharged for a desired period by flowing a small amount of current thereto. The peak values of the sawtooth waves at the terminals of the variable capacitors are alternately sampled and amplified by the same amplifier. Then, the two sampling and holding circuits alternately and independently detect the signals output from the amplifier, and the signals are subjected to a differential calculation. Thus, a small change in capacitance can be converted into voltage.

Now, characteristics of the capacitance difference detecting circuit 400 configured as described above and having the functions described above will be discussed.

First, for the purpose of comparison, characteristics of a conventional capacitance difference detecting circuit will be discussed. The current source for supplying a charging current of the conventional capacitance difference detecting circuit is a constant current source.

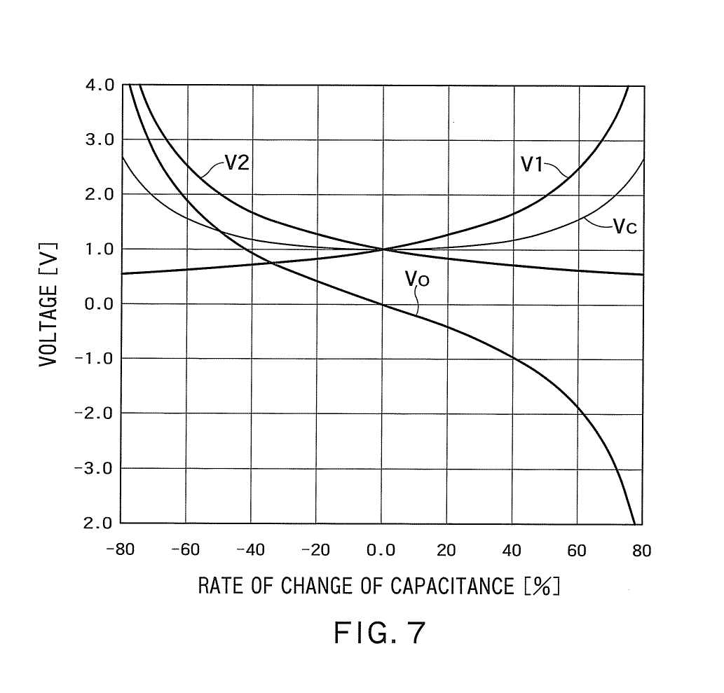

FIG. 7 is a graph showing relationships between voltages in the conventional capacitance difference detecting circuit and the rate of change of the capacitance of variable capacitors of a MEMS sensor. As shown in FIG. 7, since the charging current is constant, as the rate of change of the capacitance of the variable capacitors increases, the nonlinearity between the charging voltages “V1” and “V2” and the output “Vo” of the capacitance difference detecting circuit becomes more significant.

In other words, for the conventional capacitance difference detecting circuit, it becomes more difficult to accurately detect the capacitance difference as the change of the capacitance of the variable capacitors increases.

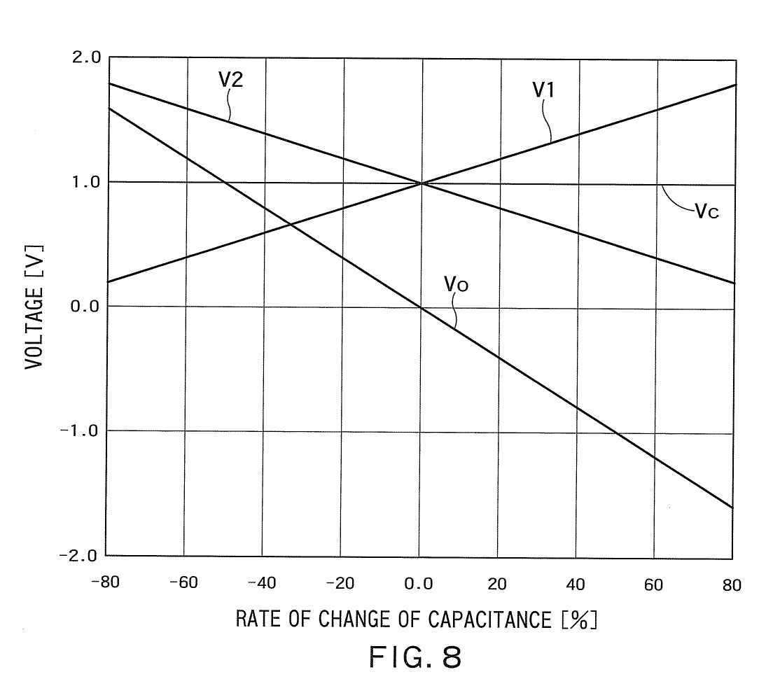

Now, characteristics of the capacitance difference detecting circuit 400 according to this embodiment will be discussed. FIG. 8 is a graph showing relationships between voltages in the capacitance difference detecting circuit and the rate of change of the capacitance of variable capacitors of a MEMS sensor.

Supposing that the charging current is “Ic”, and the charge duration is “Tc”, the detected voltages are expressed by the following formulas (9) and (10), respectively.

V1=IcTc/(C+ΔC) (9)

V2=IcTc/(C−ΔC) (10)

The sum voltage “Vc” is expressed by the following formula.

Vc=K2(V1+V2)=2K2IcTcC/((C+ΔC)(C−ΔC))

As described above, if the voltage “Vc” is kept equal to the voltage “Vs” (Vc=Vs) by the control amplifier 415 controlling the charging current “Ic”, the output “Vc” of the summing amplifier 401 is expressed by the formula (11).

Vs=Vc=2K2IcTcC/((C+ΔC)(C−ΔC)) (11)

Supposing that Vs=1, and K2=0.5, the controlled charging current “Ic” is expressed by the following formula (12).

Ic=−((C+ΔC)(C−ΔC)/TcC) (12)

The detected voltage “V1” is expressed by the following formula (13), which is derived from the formulas (9) and (12).

V1=(C−ΔC)/C (13)

The detected voltage “V2” is expressed by the following formula (14), which is derived from the formulas (10) and (12).

V2=(C+ΔC)/C (14)

Thus, the output “Vo” of the capacitance difference detecting circuit 400 is expressed by the following formula (15), which is derived from the formula (13) and (14), and is proportional to AC.

Vo=V1+V2=−2ΔC (15)

That is, if the voltage “Vc” is kept equal to the voltage “Vs” (Vc=Vs) by the control amplifier 415 controlling the charging current “Ic”, the output “Vo” of the capacitance difference detecting circuit 400 and the charging voltages “V1” and “V2” are linearly related to each other.

In this way, for the capacitance difference detecting circuit 400, the charging current “Ic” is controlled so that the sum of the sampled and held outputs is equal to a constant value, thereby improving the linearity between the output “Vo” and the charging voltages “V1” and “V2”.

Therefore, the capacitance difference detecting circuit 400 according to this embodiment can more accurately detect the capacitance difference than the conventional capacitance difference detecting circuit when the capacitance of the variable capacitors largely changes.

As described above, the capacitance difference detecting circuit can quickly and accurately detect a change in capacitance.

In this embodiment, the chopper amplifier described in the embodiments 1 and 2 can also be used. In this case, furthermore, the instrumentation amplifier configuration described in the embodiment 3 can also be used.

What is claimed is:

1. A capacitance difference detecting circuit that detects voltages charging a first variable capacitor and a second variable capacitor, the sum of the capacitances of which is constant, and outputs signals corresponding to the voltages to an output terminal, the capacitance difference detecting circuit comprising:
a current source that supplies a charging current to the first and second variable capacitors;
a current switching circuit that is connected between the current source and the first and second variable capacitors and performs a switching operation for supplying the current output from the current source to the first variable capacitor or the second variable capacitor in a complementary manner;
a chopper amplifier that detects a first charging voltage charging the first variable capacitor and a second charging voltage charging the second variable capacitor;
a first sampling and holding circuit that is connected to the output of the chopper amplifier and samples and holds an output signal of the chopper amplifier corresponding to the first charging voltage;
a second sampling and holding circuit that is connected to the output of the chopper amplifier and samples and holds an output signal of the chopper amplifier corresponding to the second charging voltage;
a differential amplifier circuit that receives the output of the first sampling and holding circuit at the inverting input terminal thereof and the output of the second sampling and holding circuit at the non-inverting input terminal thereof and outputs a signal to the output terminal; and
a timing generator that outputs a signal based on a clock signal input thereto,
wherein the timing generator
outputs a current switching pulse signal for controlling the switching operation of the current switching circuit,
outputs a gate pulse signal for controlling the chopper amplifier so that the chopper amplifier detects the first charging voltage when the first variable capacitor is charged by the first charging voltage and detects the second charging voltage when the second variable capacitor is charged by the second charging voltage,
outputs a first sample pulse signal for controlling the first sampling and holding circuit so that the first sampling and holding circuit samples and holds the output signal of the chopper amplifier when the first charging voltage is detected, and
outputs a second sample pulse signal for controlling the second sampling and holding circuit so that the second sampling and holding circuit samples and holds the output signal of the chopper amplifier when the second charging voltage is detected.

2. The capacitance difference detecting circuit according to claim 1, further comprising:
a control amplifier that sums the output of the first sampling and holding circuit and the output of the second sampling and holding circuit and controls the current source by amplifying the sum value by integration,
wherein the current source controls the charging currents so that the sum value is equal to a constant reference value.

3. The capacitance difference detecting circuit according to claim 1, wherein the timing generator outputs the current switching pulse signal so that the duration in which the first variable capacitor is charged by the charging current supplied from the current source and the duration in which the second variable capacitor is charged by the charging current supplied from the current source are equal to each other.

4. The capacitance difference detecting circuit according to claim 1, wherein the chopper amplifier comprises:
a first chopper switching circuit that is connected to the first variable capacitor at one end thereof and controlled by the timing generator;
a second chopper switching circuit that is connected to the second variable capacitor at one end thereof and controlled by the timing generator; and
an operational amplifier circuit that is connected to the other ends of the first chopper switching circuit and the second chopper switching circuit at the input thereof, amplifies the signal input thereto and outputs the amplified signal to the first sampling and holding circuit and the second sampling and holding circuit, and
wherein the timing generator
outputs a first gate pulse signal for turning on the first chopper switching circuit when the first variable capacitor is charged by the first charging voltage, and
outputs a second gate pulse signal for turning on the second chopper switching circuit when the second variable capacitor is charged by the second charging voltage.

5. The capacitance difference detecting circuit according to claim 2, wherein the chopper amplifier comprises:
a first chopper switching circuit that is connected to the first variable capacitor at one end thereof and controlled by the timing generator;
a second chopper switching circuit that is connected to the second variable capacitor at one end thereof and controlled by the timing generator; and
an operational amplifier circuit that is connected to the other ends of the first chopper switching circuit and the second chopper switching circuit at the input thereof, amplifies the signal input thereto and outputs the amplified signal to the first sampling and holding circuit and the second sampling and holding circuit, and
wherein the timing generator
outputs a first gate pulse signal for turning on the first chopper switching circuit when the first variable capacitor is charged by the first charging voltage, and
outputs a second gate pulse signal for turning on the second chopper switching circuit when the second variable capacitor is charged by the second charging voltage.

6. The capacitance difference detecting circuit according to claim 3, wherein the chopper amplifier comprises:
a first chopper switching circuit that is connected to the first variable capacitor at one end thereof and controlled by the timing generator;
a second chopper switching circuit that is connected to the second variable capacitor at one end thereof and controlled by the timing generator; and
an operational amplifier circuit that is connected to the other ends of the first chopper switching circuit and the second chopper switching circuit at the input thereof, amplifies the signal input thereto and outputs the amplified signal to the first sampling and holding circuit and the second sampling and holding circuit, and
wherein the timing generator
outputs a first gate pulse signal for turning on the first chopper switching circuit when the first variable capacitor is charged by the first charging voltage, and
outputs a second gate pulse signal for turning on the second chopper switching circuit when the second variable capacitor is charged by the second charging voltage.

7. The capacitance difference detecting circuit according to claim 1, wherein the first variable capacitor and the second variable capacitor form a MEMS sensor.

8. The capacitance difference detecting circuit according to claim 2, wherein the first variable capacitor and the second variable capacitor form a MEMS sensor.

9. The capacitance difference detecting circuit according to claim 3, wherein the first variable capacitor and the second variable capacitor form a MEMS sensor.

10. The capacitance difference detecting circuit according to claim 4, wherein the first variable capacitor and the second variable capacitor form a MEMS sensor.

11. The capacitance difference detecting circuit according to claim 5, wherein the first variable capacitor and the second variable capacitor form a MEMS sensor.

12. The capacitance difference detecting circuit according to claim 6, wherein the first variable capacitor and the second variable capacitor form a MEMS sensor.

13. A capacitance difference detecting circuit that detects voltages charging a first variable capacitor and a second variable capacitor, the sum of the capacitances of which is constant, and outputs differential signals corresponding to the voltages to a first output terminal and a second output terminal, respectively, the capacitance difference detecting circuit comprising:
a current source that supplies a current to the first and second variable capacitors;
a current switching circuit that is connected between the current source and the first and second variable capacitors and performs a switching operation for supplying the current output from the current source to the first variable capacitor or the second variable capacitor in a complementary manner;
a chopper amplifier that detects a first charging voltage charging the first variable capacitor and a second charging voltage charging the second variable capacitor;
a first sampling and holding circuit that has a first sampling/holding switching circuit connected to the output of the chopper amplifier at one end thereof and a first capacitor connected between the other end of the first sampling/holding switching circuit and the ground and samples and holds the output of the chopper amplifier corresponding to the first charging voltage by charging the first capacitor by the voltage corresponding to the output of the chopper amplifier;
a second sampling and holding circuit that has a second sampling/holding switching circuit connected to the output of the chopper amplifier at one end thereof and a second capacitor connected between the other end of the second sampling/holding switching circuit and the ground and samples and holds the output of the chopper amplifier corresponding to the second charging voltage by charging the second capacitor by the voltage corresponding to the output of the chopper amplifier;
a first differential amplifier circuit that receives the voltage of the first capacitor at the non-inverting input terminal thereof and outputs a signal to the first output terminal;
a second differential amplifier circuit that receives the voltage of the second capacitor at the non-inverting input terminal thereof and outputs a signal to the second output terminal;
a first resistor connected between the output and the inverting input terminal of the first differential amplifier circuit;
a second resistor connected to the inverting input terminal of the first differential amplifier circuit at one end thereof;
a third resistor that is connected between the output and the inverting input terminal of the second differential amplifier circuit and has a resistance equal to the resistance of the first resistor;
a fourth resistor that is connected between the inverting input terminal of the second differential amplifier circuit and the other end of the second resistor and has a resistance equal to the resistance of the second resistor;
a timing generator that outputs a signal based on a clock signal input thereto; and
a control amplifier that amplifies the voltage between the second resistor and the fourth resistor by integration to control the current source,
wherein the timing generator
outputs a current switching pulse signal for controlling the switching operation of the current switching circuit,
outputs a gate pulse signal for controlling the chopper amplifier so that the chopper amplifier detects the first charging voltage when the first variable capacitor is charged by the first charging voltage and detects the second charging voltage when the second variable capacitor is charged by the second charging voltage,
outputs a first sample pulse signal for controlling the first sampling/holding switching circuit of the first sampling and holding circuit so that the first sampling and holding circuit samples and holds the output signal of the chopper amplifier when the first charging voltage is detected, and
outputs a second sample pulse signal for controlling the second sampling/holding switching circuit of the second sampling and holding circuit so that the second sampling and holding circuit samples and holds the output signal of the chopper amplifier when the second charging voltage is detected, and
the control amplifier controls the charging current from the current source so that the voltage between the second resistor and the fourth resistor is equal to a constant reference value.

14. The capacitance difference detecting circuit according to claim 13, wherein the timing generator outputs the current switching pulse signal so that the duration in which the first variable capacitor is charged by the charging current supplied from the current source and the duration in which the second variable capacitor is charged by the charging current supplied from the current source are equal to each other.

15. The capacitance difference detecting circuit according to claim 13, wherein the first variable capacitor and the second variable capacitor form a MEMS sensor.

16. The capacitance difference detecting circuit according to claim 14, wherein the first variable capacitor and the second variable capacitor form a MEMS sensor.

17. A capacitance difference detecting circuit that detects voltages charging a first variable capacitor and a second variable capacitor, the sum of the capacitances of which is constant, and outputs signals corresponding to the voltages to an output terminal, the capacitance difference detecting circuit comprising:
a current source that supplies a charging current to the first and second variable capacitors;
a current switching circuit that is connected between the current source and the first and second variable capacitors and performs a switching operation for supplying the current output from the current source to the first variable capacitor or the second variable capacitor in a complementary manner;
a first sampling and holding circuit that samples and holds a signal corresponding to a first charging voltage charging the first variable capacitor;
a second sampling and holding circuit that samples and holds a signal corresponding to a second charging voltage charging the second variable capacitor;
a differential amplifier circuit that receives the output of the first sampling and holding circuit at the inverting input terminal thereof and the output of the second sampling and holding circuit at the non-inverting input terminal thereof and outputs a signal to the output terminal;
a timing generator that outputs a signal based on a clock signal input thereto;
a summing amplifier that sums the output of the first sampling and holding circuit and the output of the second sampling and holding circuit and amplifies the sum result; and
a control amplifier that controls the charging current by outputting a control voltage, which is the output of the summing amplifier amplified by integration so that the output of the summing amplifier is equal to a constant reference value, to the current source,
wherein the timing generator
outputs a current switching pulse signal for controlling the switching operation of the current switching circuit,
outputs a first sample pulse signal for controlling the first sampling and holding circuit so that the first sampling and holding circuit samples and holds the signal corresponding to the first charging voltage when the first variable capacitor is charged by the first charging voltage, and
outputs a second sample pulse signal for controlling the second sampling and holding circuit so that the second sampling and holding circuit samples and holds the signal corresponding to the second charging voltage when the second variable capacitor is charged by the second charging voltage.

18. The capacitance difference detecting circuit according to claim 17, wherein the timing generator outputs the current switching pulse signal so that the duration in which the first variable capacitor is charged by the charging current supplied from the current source and the duration in which the second variable capacitor is charged by the charging current supplied from the current source are equal to each other.

19. The capacitance difference detecting circuit according to claim 17, wherein the first variable capacitor and the second variable capacitor form a MEMS sensor.

20. The capacitance difference detecting circuit according to claim 18, wherein the first variable capacitor and the second variable capacitor form a MEMS sensor.
